(19) United States
(12) Patent Application Publication
(10) Pub. No.: US 2019/0214536 A1
(43) Pub. Date: Jul. 11, 2019

(54) METHOD OF PRODUCING AN OPTOELECTRONIC COMPONENT, AND OPTOELECTRONIC COMPONENT

(71) Applicant: OSRAM Opto Semiconductors GmbH, Regensburg (DE)

(72) Inventors: Tobias Gebuhr, Regensburg (DE); Markus Pindl, Tegernheim (DE)

(73) Assignee: OSRAM Opto Semiconductors GmbH, Regensburg (DE)

(21) Appl. No.: 16/315,319

(22) PCT Filed: Jul. 5, 2017
(86) PCT No.: PCT/EP2017/066792

§ 371 Date: Jan. 4, 2019

(30) Foreign Application Priority Data
Jul. 5, 2016 (DE) 10 2016 112 293.9

(51) Int. Cl. H01L 33/60; H01L 33/56; H01L 33/00; H01L 33/48; H01L 33/50

(52) U.S. Cl. CPC H01L 33/60; H01L 33/56; H01L 33/0095; H01L 2933/005; H01L 33/502; H01L 2933/0033; H01L 2933/0041; H01L 33/486

(57) ABSTRACT

A method of producing an optoelectronic component includes providing a carrier; arranging a structured reflector above a top side of the carrier; arranging an optoelectronic semiconductor chip including a top side and an underside opposite the top side in an opening of the reflector, wherein the underside of the optoelectronic semiconductor chip faces the top side of the carrier; arranging an embedding material above the top side of the carrier, wherein the optoelectronic semiconductor chip is at least partly embedded into the embedding material, as a result of which a composite body including the optoelectronic semiconductor chip, the reflector and the embedding material is formed; and detaching the composite body from the carrier.

### TECHNICAL FIELD

This disclosure relates to a method of producing an optoelectronic component, and an optoelectronic component.

### BACKGROUND

Optoelectronic components, for example, light-emitting diode components are known in which an optoelectronic semiconductor chip is embedded into an embedding material that forms a housing comprising extremely compact dimensions. It is known to use optically reflective embedding material so that light emitted by the optoelectronic semiconductor chips in lateral directions is deflected in a forward direction.

### SUMMARY

We provide a method of producing an optoelectronic component including providing a carrier; arranging a structured reflector above a top side of the carrier; arranging an optoelectronic semiconductor chip including a top side and an underside opposite the top side in an opening of the reflector, wherein the underside of the optoelectronic semiconductor chip faces the top side of the carrier; arranging an embedding material above the top side of the carrier, wherein the optoelectronic semiconductor chip is at least partly embedded into the embedding material, as a result of which a composite body including the optoelectronic semiconductor chip, the reflector and the embedding material is formed; and detaching the composite body from the carrier.

We also provide an optoelectronic component including a composite body including an embedding material, a reflector, and an optoelectronic semiconductor chip, wherein the optoelectronic semiconductor chip is at least partly embedded into the embedding material, the optoelectronic semiconductor chip is arranged in an opening of the reflector, and an underside of the optoelectronic semiconductor chip and an underside of the reflector terminate flush and are at least partly exposed at an underside of the composite body.

### BRIEF DESCRIPTION OF THE DRAWINGS

FIG. 1 schematically shows a sectional side view of a carrier.

FIG. 2 schematically shows a sectional side view of the carrier with a structured reflector arranged above the top side of the carrier.

FIG. 3 schematically shows a sectional side view of the carrier with optoelectronic semiconductor chips arranged in openings of the structured reflector.

FIG. 4 schematically shows a plan view of the top side of the carrier with the structured reflector and the optoelectronic semiconductor chips.

FIG. 5 schematically shows a sectional side view of the carrier, of the structured reflector and of the optoelectronic semiconductor chips with wavelength-converting films arranged on top sides of the optoelectronic semiconductor chips.

FIG. 6 schematically shows a sectional side view of the carrier with an embedding material arranged above the top side of the carrier, the structured reflector and the optoelectronic semiconductor chips being embedded into the embedding material.

FIG. 7 schematically shows a sectional side view of a composite body formed from the embedding material, the structured reflector and the optoelectronic semiconductor chips, after the process of detaching from the carrier.

FIG. 8 schematically shows a sectional side view of optoelectronic components formed by dividing the composite body.

FIG. 9 schematically shows a plan view of the optoelectronic components.

### LIST OF REFERENCE SIGNS

10 Optoelectronic component
100 Carrier
101 Top side
110 Adhesive film
200 Structured reflector
201 Top side
202 Underside
210 Opening
300 Optoelectronic semiconductor chip
301 Top side
302 Underside
310 Electrical contact pad
320 Distance
400 Embedding material
410 Wavelength-converting film
500 Composite body
501 Top side
502 Underside

### DETAILED DESCRIPTION

Our method of producing an optoelectronic component comprises steps of providing a carrier; arranging a structured reflector above a top side of the carrier, arranging an optoelectronic semiconductor chip comprising a top side and an underside opposite the top side in an opening of the reflector, wherein the underside of the optoelectronic semiconductor chip faces the top side of the carrier, arranging an embedding material above the top side of the carrier, wherein the optoelectronic semiconductor chip is at least partly embedded into the embedding material, as a result of which a composite body comprising the optoelectronic semiconductor chip, the reflector and the embedding material is formed, and detaching the composite body from the carrier.

In the optoelectronic component obtained by this method, the reflector may reflect light emitted by the optoelectronic semiconductor chip and thereby bring about a deflection of the light in a preferred emission direction. As a result, light emitted by the optoelectronic component obtained by the method is at least partly directed. Since light emitted by the optoelectronic semiconductor chip in other spatial directions is at least partly deflected in the preferred emission direction at the reflector and is thus utilized, the light is not lost. As a result, the optoelectronic component obtained by the method may comprise a high brightness and a high efficiency.

The optoelectronic component obtained by the method may advantageously comprise very compact external dimensions. This is achieved in particular by virtue of the fact that the optoelectronic component need not comprise any further major component parts apart from the optoelectronic semiconductor chip, the reflector, and the embedding material.

The reflector may be formed as a flat sheet or as a flat film, in particular as a metallic leadframe or as a metal film. Advantageously, the reflector comprises a high optical reflectivity as a result. Moreover, the reflector is obtainable simply and cost-effectively. Structuring the reflector may be carried out by laser cutting, for example.

The carrier may be provided with an adhesive film arranged at its top side, in particular with an adhesive film releasable by thermal treatment or by electromagnetic irradiation. In this example, the reflector is arranged on the adhesive film. Advantageously, providing the adhesive film enables a simple and reliable later detachment of the composite body from the carrier. This reduces the risk of damage to the composite body and the risk of damage to the optoelectronic component produced. For the purpose of detaching the composite body, the adhesiveness of the adhesive film may be reduced, for example, by a thermal treatment or electromagnetic irradiation, for example, irradiation with UV light.

One or more electrical contact pads of the optoelectronic semiconductor chip may be arranged at the underside of the optoelectronic semiconductor chip. The electrical contact pads may electrically contact the optoelectronic semiconductor chip and may form electrical connection pads in the optoelectronic component obtained by the method.

The optoelectronic semiconductor chip may be formed as a flip-chip. By way of example, the optoelectronic semiconductor chip may be formed as a sapphire flip-chip.

The optoelectronic semiconductor chip may be formed as a volume emitting light-emitting diode chip. Advantageously, in the optoelectronic component obtained by the method, light emitted by the volume emitting light-emitting diode chip in spatial directions that do not correspond to the preferred emission direction of the optoelectronic component is at least partly reflected at the reflector of the optoelectronic component and deflected in the preferred emission direction. As a result, these portions of the light emitted by the optoelectronic semiconductor chip are also at least partly utilized.

The top side of the optoelectronic semiconductor chip may be covered by the embedding material. This advantageously makes it possible to carry out the process of arranging the embedding material by a particularly simple process step that may be carried out cost-effectively. Covering the top side of the optoelectronic semiconductor chip by the embedding material is made possible by the fact that the embedding material may be formed as optically transparent. This in turn is made possible by the fact that the embedding material need not reflect light emitted in undesired spatial directions. Rather, the reflector reflects such light in the optoelectronic component obtained by the method.

The embedding material may comprise a silicone. Advantageously, the embedding material may thereby be cost-effectively obtainable and easy to process. Moreover, the embedding material may comprise a high durability. In particular, an embedding material comprising a silicone may comprise a reduced susceptibility to cracking compared to other embedding materials. The use of an embedding material comprising a silicone may also support detaching the composite body from the carrier without any problems.

The embedding material may comprise embedded wavelength-converting particles. The wavelength-converting particles embedded into the embedding material may be provided to at least partly convert light emitted by the optoelectronic semiconductor chip into light comprising a different wavelength. As a result, in the optoelectronic component obtained by the method, by way of example, white light may be generated from light emitted by the optoelectronic semiconductor chip and comprising a wavelength from the blue or ultraviolet spectral range, the white light being emitted by the optoelectronic component.

Arranging the embedding material may be carried out by a molding process or a casting process. Advantageously, arranging the embedding material may be carried out simply and cost-effectively as a result.

Before arranging the embedding material, a further step may be carried out by arranging a film comprising a wavelength-converting material above the top side of the optoelectronic semiconductor chip. Afterward, the film is embedded into the embedding material such that the composite body also comprises the film. In the optoelectronic component obtained by this method, the wavelength-converting material of the film may at least partly convert light emitted by the optoelectronic semiconductor chip into light comprising a different wavelength. As a result, the embedding material need not comprise embedded wavelength-converting particles.

The optoelectronic semiconductor chip may be arranged in the opening of the reflector such that a distance between the optoelectronic semiconductor chip and the reflector is of identical magnitude on all sides of the optoelectronic semiconductor chip. In this example, the distance between the optoelectronic semiconductor chip and the reflector that is identical on all sides of the optoelectronic semiconductor chip is maintained within the scope of the positioning accuracy of the optoelectronic semiconductor chip. A distance between the optoelectronic semiconductor chip and the reflector that is as far as possible identical on all sides of the optoelectronic semiconductor chip may advantageously support a particularly homogeneous light emission of the optoelectronic component obtained by the method.

The reflector may be formed as a grid comprising a plurality of openings. The openings may be created by laser cutting, for example.

A plurality of optoelectronic semiconductor chips may be arranged respectively in openings of the reflector. In this example, the composite body formed comprises all the optoelectronic semiconductor chips. After detaching the composite body, a further step of dividing the composite body is carried out. As a result, the method advantageously makes it possible to simultaneously produce a plurality of optoelectronic components in common processing steps. The production costs per optoelectronic component and the work time required to produce an optoelectronic component are reduced as a result.

An optoelectronic component comprises a composite body comprising an embedding material, a reflector and an optoelectronic semiconductor chip. In this example, the optoelectronic semiconductor chip is at least partly embedded into the embedding material. The optoelectronic semiconductor chip is arranged in an opening of the reflector. In this example, an underside of the optoelectronic semiconductor chip and an underside of the reflector terminate flush and are at least partly exposed at an underside of the composite body.

In the optoelectronic component, the reflector at least partly reflects light emitted by the optoelectronic semiconductor chip in spatial directions that do not correspond to a desired emission direction of the optoelectronic component, and thereby deflects the light in the desired emission direction of the optoelectronic component. As a result, the deflected light is made usable and not lost. As a result, the optoelectronic component may advantageously comprise a high brightness and a high efficiency.

One or more electrical contact pads of the optoelectronic semiconductor chip may be arranged at the underside of the optoelectronic semiconductor chip and are exposed at the underside of the composite body. As a result, the electrical contact pads of the optoelectronic semiconductor chip form electrical contacts of the optoelectronic component and enable electrical contacting of the optoelectronic component. The optoelectronic component may be suitable, for example, for surface mounting, for example, surface mounting by reflow soldering.

A top side of the optoelectronic semiconductor chip opposite the underside may be covered by the embedding material. Advantageously, this enables simple and cost-effective production of the optoelectronic component. Moreover, the embedding material covering the top side of the optoelectronic semiconductor chip may as a result also at least partly convert light emitted by the optoelectronic semiconductor chip into light comprising a different wavelength.

The optoelectronic component may comprise no further major component parts apart from the composite body. Advantageously, the optoelectronic component may comprise very compact external dimensions as a result.

A distance between the optoelectronic semiconductor chip and the reflector may be of identical magnitude on all sides of the optoelectronic semiconductor chip. In this example, the distance between the optoelectronic semiconductor chip and the reflector that is identical on all sides of the optoelectronic semiconductor chip is maintained within the scope of the production accuracy. A distance between the optoelectronic semiconductor chip and the reflector of the optoelectronic component that is identical on all sides of the optoelectronic semiconductor chip may advantageously support a particularly homogeneous light emission by the optoelectronic component.

The above-described properties, features and advantages and the way in which they are achieved will become clearer and more clearly understood in association with the following description of examples explained in greater detail in association with the drawings.

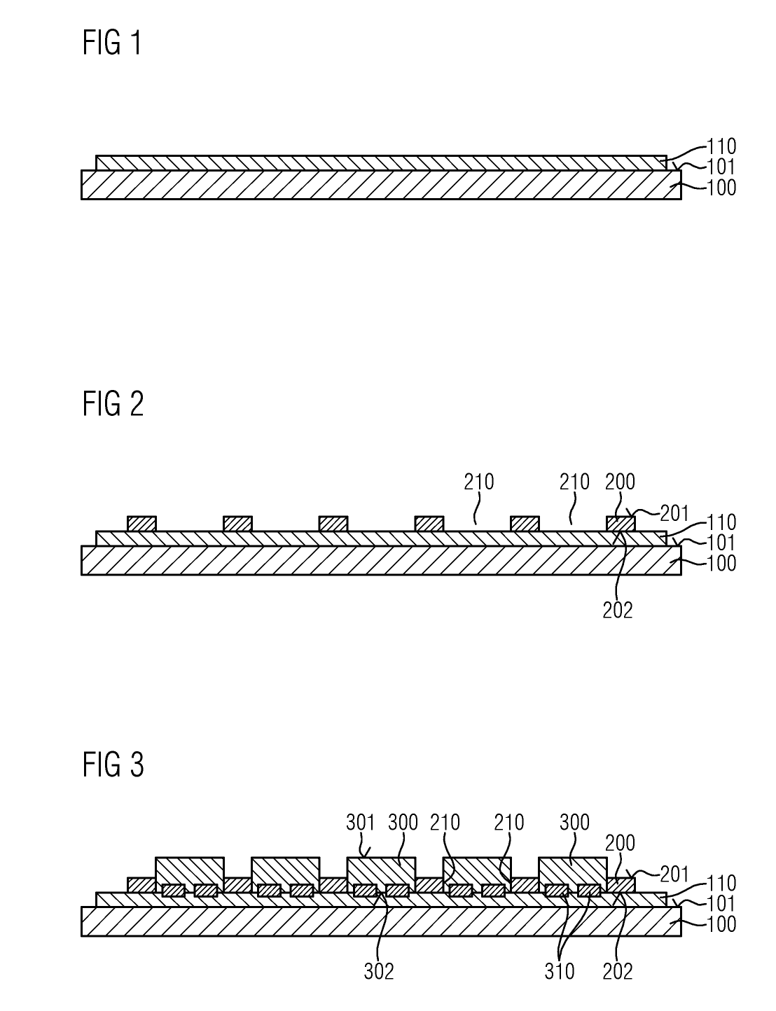

FIG. 1 shows a schematic sectional side view of a carrier 100. The carrier 100 comprises a planar top side 101. The carrier 100 may be formed as a metal plate, for example.

An adhesive film 110 is arranged at the top side 101 of the carrier 100. The adhesive film 110 may be, for example, an adhesive film releasable by thermal treatment or electromagnetic irradiation. In this example, the adhesiveness of the adhesive film 110 on one or on both sides of the adhesive film 110 may be reduced by a thermal treatment, for example, by heating or electromagnetic irradiation, for example, irradiation with UV light.

FIG. 2 shows a schematic sectional side view of the carrier 100 and of the adhesive film 110 in a processing state temporally succeeding the illustration in FIG. 1.

A structured reflector 200 has been arranged on the adhesive film 110 above the top side 101 of the carrier 100. The structured reflector 200 is formed as a thin, flat sheet or as a thin, flat film. The structured reflector 200 comprises a top side 201 and an underside 202 opposite the top side 201. The underside 202 of the structured reflector 200 faces the top side 101 of the carrier 100.

The structured reflector 200 may comprise a metal, for example. The structured reflector 200 may be formed, for example, as a metallic leadframe or as a metal film.

The structured reflector 200 comprises a plurality of openings 210 extending through the structured reflector 200. The openings 210 are preferably arranged in a regular arrangement, for example, in a regular matrix arrangement. As a result, the structured reflector 200 is formed as a grid.

The openings 210 may have been introduced into the structured reflector 200 by laser cutting, for example. In this example, the material of the structured reflector 200 was cut out in the region of the openings 210 by a laser beam. Structuring the reflector 200, that is to say creating the openings 210, may already have been carried out before arranging the structured reflector 200 above the top side 101 of the carrier 100.

The openings 210 may each comprise a rectangular, in particular a square, cross section. However, the openings 210 may, for example, also comprise circular-disk-shaped or other cross sections.

FIG. 3 shows a schematic sectional side view of the carrier 100, the adhesive film 110 and the structured reflector 200 in a processing state temporally succeeding the illustration in FIG. 2.

Optoelectronic semiconductor chips 300 have been arranged in the openings 210 of the structured reflector 200. The optoelectronic semiconductor chips 300 are configured to emit electromagnetic radiation, for example, visible light. The optoelectronic semiconductor chips 300 may be formed, for example, as light-emitting diode chips. By way of example, the optoelectronic semiconductor chips 300 may be formed as volume emitting light-emitting diode chips.

Each optoelectronic semiconductor chip 300 comprises a top side 301 and an underside 302 opposite the top side 301. The optoelectronic semiconductor chips 300 are configured to emit electromagnetic radiation at their top sides 301 during operation. In addition, the optoelectronic semiconductor chips 300 may also be configured to emit electromagnetic radiation at side faces extending between the top sides 301 and the undersides 302. In this example, electromagnetic radiation emitted at the side surfaces is emitted in a lateral direction.

The optoelectronic semiconductor chips 300 each comprise electrical contact pads 310 at their undersides 302. The optoelectronic semiconductor chips 300 may be formed, for example, as flip-chips, in particular, for example, as sapphire flip-chips. The electrical contact pads 310 of the optoelectronic semiconductor chips 300 make it possible to apply electrical voltage and electrical current to the optoelectronic semiconductor chips 300.

A respective optoelectronic semiconductor chip 300 has been arranged in each opening 210 of the structured reflector 200. The optoelectronic semiconductor chips 300 have been placed onto the adhesive film 110 in the openings 210 of the structured reflector 200. In this example, the optoelectronic semiconductor chips 300 have been arranged such that the undersides 302 of the optoelectronic semiconductor chips 300 face the top side 101 of the carrier 100. Arranging the optoelectronic semiconductor chips 300 in the openings 210 of the structured reflector 200 may have been carried out by a pick-and-place method, for example.

The optoelectronic semiconductor chips 300 each comprise, in a direction oriented perpendicularly to their top sides 301, a thickness measured from the top side 301 as far as the underside 302 which is larger than a thickness of the structured reflector 200 measured in a direction perpendicular to the top side 201 of the structured reflector 200 from the top side 201 as far as the underside 202. As a result, the optoelectronic semiconductor chips 300 arranged above the top side 101 of the carrier 100 in the openings 210 of the structured reflector 200 project beyond the top side 201 of the structured reflector 200.

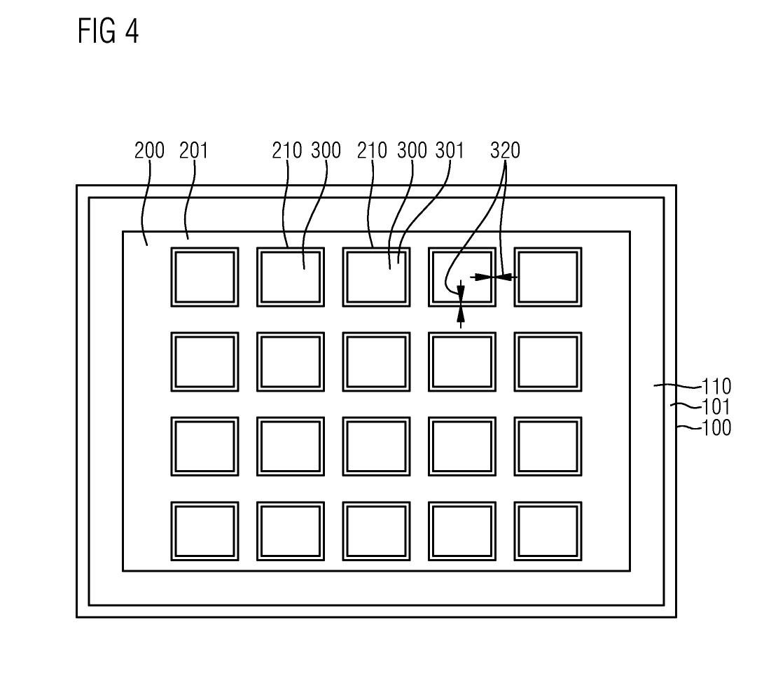

FIG. 4 shows, in schematic illustration, a plan view of the top side 101 of the carrier with the adhesive film 110 arranged at the top side 101 of the carrier 100, the structured reflector 200 arranged at the adhesive film 110, and the semiconductor chips 300 arranged in the openings 210 of the structured reflector 200. The top side 201 of the structured reflector 200 and the top sides 301 of the optoelectronic semiconductor chips 300 are visible.

It is expedient for the openings 210 of the structured reflector 200 to comprise a similar shape to the top sides 301 and undersides 302 of the optoelectronic semiconductor chips 300. In the example illustrated, both the openings 210 of the structured reflector 200 and the top sides 301 and undersides 302 of the optoelectronic semiconductor chips 300 comprise rectangular shapes. In this example, the openings 210 of the structured reflector 200 are somewhat larger than the top sides 301 and undersides 302 of the optoelectronic semiconductor chips 300. As a result, the optoelectronic semiconductor chips 300 arranged in the openings 210 of the structured reflector 200 are not in contact with the structured reflector 200. Rather, a distance 320 between the optoelectronic semiconductor chips 300 and the edges of the openings 210 of the structured reflector 200 results on all sides around the optoelectronic semiconductor chips 300. It is expedient for the distance 320 between the optoelectronic semiconductor chips 300 and the structured reflector 200 to be approximately of identical magnitude on all sides of the optoelectronic semiconductor chips 300. For this purpose, the optoelectronic semiconductor chips 300, within the scope of the achievable production accuracy, are positioned centrally in the openings 210 of the structured reflector 200.

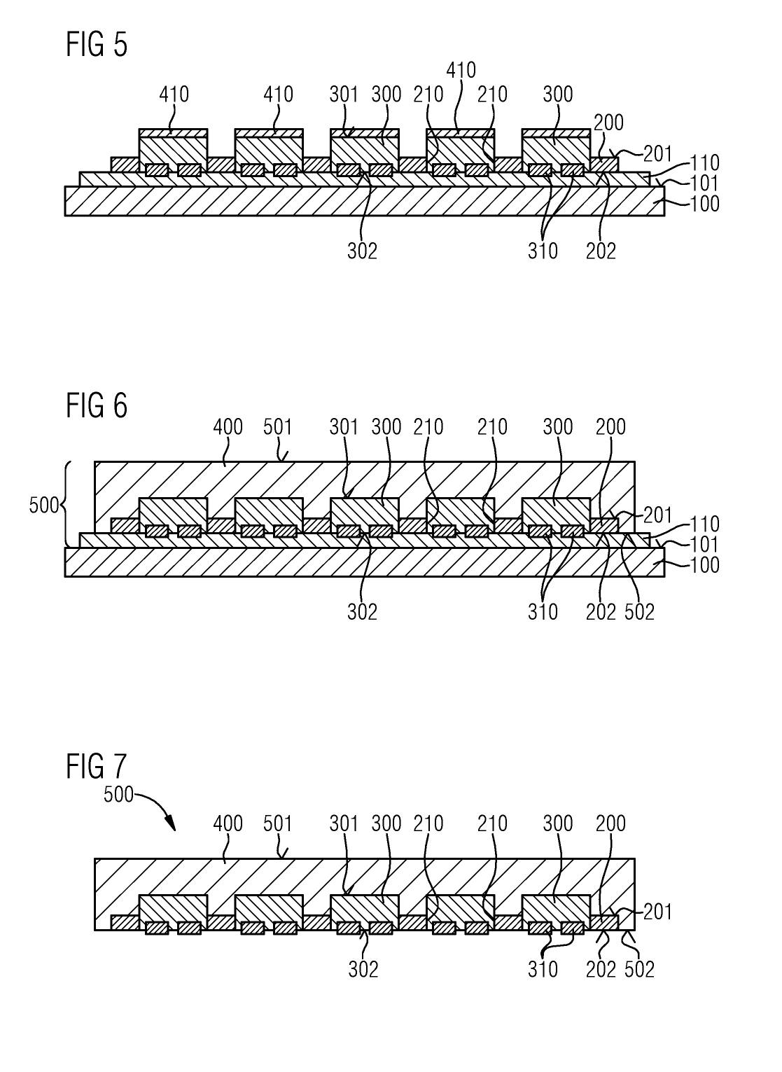

FIG. 5 shows a schematic sectional side view of the carrier 100 with the adhesive film 110, the structured reflector 200 and the optoelectronic semiconductor chips 300 in a processing state temporally succeeding the illustration in FIG. 3.

Wavelength-converting films 410 have been arranged at the top sides 301 of the optoelectronic semiconductor chips 300 arranged above the top side 101 of the carrier 100. Arranging the wavelength-converting films 410 may have been carried out, for example, by laminating the wavelength-converting films 410 onto the top sides 301 of the optoelectronic semiconductor chips 300.

The wavelength-converting films 410 each comprise a wavelength-converting material. The wavelength-converting material of the wavelength-converting films 410 is configured to at least partly convert electromagnetic radiation emitted by the optoelectronic semiconductor chips 300 into electromagnetic radiation comprising a different wavelength. By way of example, the wavelength-converting material of the wavelength-converting films 410 may convert electromagnetic radiation emitted by the optoelectronic semiconductor chips 300 and comprising a wavelength from the blue or ultraviolet spectral range into yellow light. A mixture of unconverted light of the optoelectronic semiconductor chips 300 and light converted by the wavelength-converting material of the wavelength-converting films 410 may comprise a white light color, for example.

In the example shown in FIG. 5, a dedicated section of a wavelength-converting film 410 each has been arranged at each optoelectronic semiconductor chip 300. It would also be possible to provide a continuous wavelength-converting film 410 extending over the top sides 301 of all the optoelectronic semiconductor chips 300 and divided in a later processing step.

The step of arranging the wavelength-converting films 410 may optionally be dispensed with. The further description of the production method will dispense with an illustration of the wavelength-converting films 410.

FIG. 6 shows a schematic sectional side view of the carrier 100 with the adhesive film 110, the structured reflector 200 and the optoelectronic semiconductor chips 300 in a processing state temporally succeeding the illustration in FIG. 3.

An embedding material 400 has been arranged above the top side 101 of the carrier 100. In this example, the optoelectronic semiconductor chips 300 were at least partly embedded into the embedding material 400. The structured reflector 200 was also at least partly embedded into the embedding material 400. A composite body 500 comprising the optoelectronic semiconductor chips 300, the structured reflector 200 and the embedding material 400 has been formed as a result.

If the wavelength-converting films 410 had been arranged on the top sides 301 of the optoelectronic semiconductor chips 300 in a previous processing step, then they would likewise have been embedded into the embedding material 400 and then likewise be part of the composite body 500.

Arranging the embedding material 400 above the top side 101 of the carrier 100 may have been carried out, for example, by a molding or casting process. A further processing step of curing the embedding material 400 may have been carried out after arranging the embedding material 400.

The top sides 301 of the optoelectronic semiconductor chips 300 are covered by the embedding material 400. However, it would also be possible for the top sides 301 of the optoelectronic semiconductor chips 300 not to be covered by the embedding material 400.

The composite body 500 formed by embedding the optoelectronic semiconductor chips 300 and the structured reflector 200 into the embedding material 400 comprises a top side 501 and an underside 502 opposite the top side 501. The top side 501 of the composite body 500 is formed by the embedding material 400. The underside 502 of the composite body 500 faces the top side 101 of the carrier 100 and is in contact with the adhesive film 110.

The embedding material 400 is at least partly transparent to electromagnetic radiation emitted by the optoelectronic semiconductor chips 300. The embedding material 400 may comprise a silicone, for example. In addition, the embedding material 400 may comprise embedded wavelength-converting particles. The wavelength-converting particles embedded into the embedding material 400 may be configured to at least partly convert electromagnetic radiation emitted by the optoelectronic semiconductor chips 300 into electromagnetic radiation comprising a different wavelength. By way of example, the wavelength-converting particles may be configured to convert electromagnetic radiation emitted by the optoelectronic semiconductor chips 300 and comprising a wavelength from the blue or ultraviolet spectral range into yellow light. A mixture of unconverted and converted light may comprise a white light color, for example. If wavelength-converting films 410 have been arranged at the top sides 301 of the optoelectronic semiconductor chips 300 in a preceding processing step, then wavelength-converting particles provided in the embedding material 400 may be dispensed with. Moreover, the wavelength-converting particles may be omitted if no wavelength converting is required.

FIG. 7 shows a schematic sectional side view of the composite body 500 comprising the optoelectronic semiconductor chips 300, the structured reflector 200 and the embedding material 400 in a processing state temporally succeeding the illustration in FIG. 6.

The composite body 500 has been detached from the carrier 100. The adhesive film 110 has also been removed from the composite body 500. To remove the carrier 100 and the adhesive film 110 from the underside 502 of the composite body 500, an adhesiveness of the adhesive film 110 may have been reduced on one or on both sides of the adhesive film 110, for example, by a thermal treatment of the adhesive film 110 or an irradiation of the adhesive film 110 with electromagnetic radiation.

After detaching the composite body 500 from the carrier 100, the underside 502 of the composite body 500 is exposed. At the underside 502 of the composite body 500, the undersides 302 of the optoelectronic semiconductor chips 300 and the underside 202 of the structured reflector 200 terminate flush with one another. The undersides 302 of the optoelectronic semiconductor chips 300 and the underside 202 of the structured reflector 200 are not covered by the embedding material 400 and are thus exposed at the underside 502 of the composite body 500. As a result, the electrical contact pads 310 arranged at the undersides 302 of the optoelectronic semiconductor chips 300 are also exposed at the underside 502 of the composite body 500.

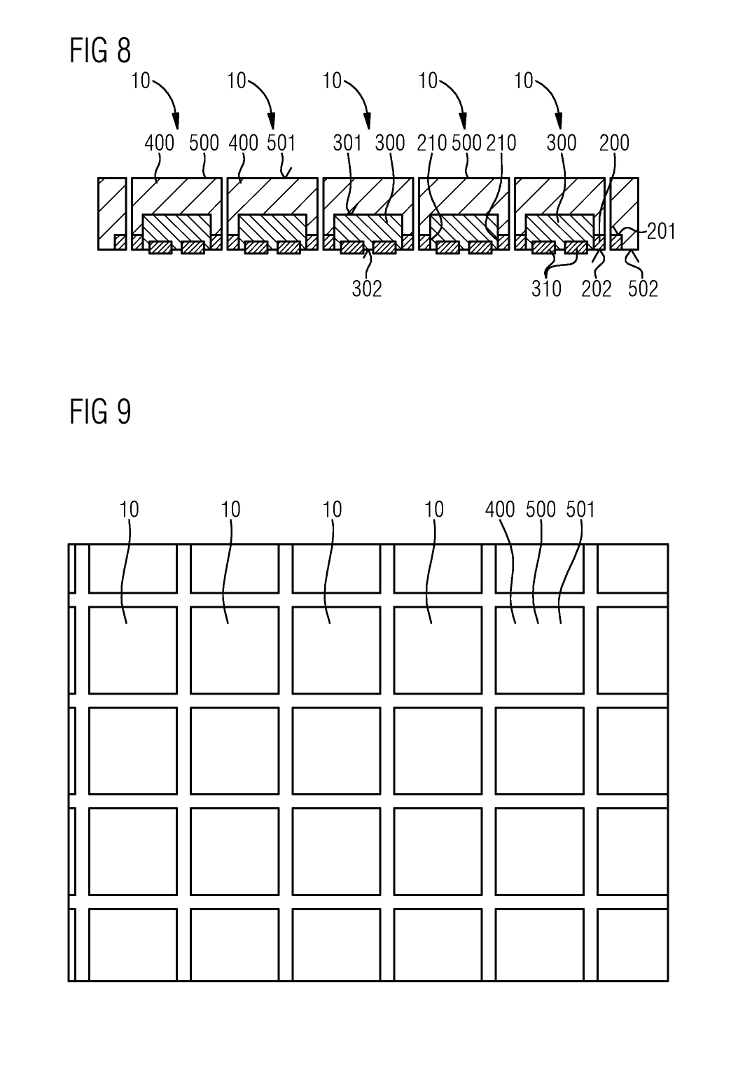

FIG. 8 shows a schematic sectional side view of the composite body 500 in a processing state temporally succeeding the illustration in FIG. 7.

The composite body 500 has been divided into a plurality of parts each comprising an optoelectronic semiconductor chip 300. Each of these parts of the composite body 500 forms an optoelectronic component 10. FIG. 9 shows a plan view of the top side 501 of the divided composite body 500 in a schematic illustration.

Dividing the composite body 500 may have been carried out by a sawing process, for example. In this example, the sawing cuts extend between the optoelectronic semiconductor chips 300 through the embedding material 400 and through the structured reflector 200.

The optoelectronic components 10 formed by dividing the composite body 500 each comprise no further major component parts or other housing parts apart from the respective part of the composite body 500.

The electrical contact pads 310 of the optoelectronic semiconductor chips 300 that are exposed at the undersides 302 of the optoelectronic semiconductor chips 300 form electrical contacts to electrically contact the optoelectronic components 10. The optoelectronic components 10 may be provided, for example, as SMD components for surface mounting, for example, for surface mounting by reflow soldering.

Our methods and components have been illustrated and described in greater detail on the basis of preferred examples. Nevertheless, this disclosure is not restricted to the examples disclosed. Rather, other variations may be derived therefrom by those skilled in the art, without departing from the scope of protection of the appended claims.

This application claims priority of DE 10 2016 112 293.9, the subject matter of which is incorporated herein by reference.

1.-19. (canceled)

20. A method of producing an optoelectronic component comprising:
providing a carrier;
arranging a structured reflector above a top side of the carrier;
arranging an optoelectronic semiconductor chip comprising a top side and an underside opposite the top side in an opening of the reflector, wherein the underside of the optoelectronic semiconductor chip faces the top side of the carrier;
arranging an embedding material above the top side of the carrier, wherein the optoelectronic semiconductor chip is at least partly embedded into the embedding material, as a result of which a composite body comprising the optoelectronic semiconductor chip, the reflector and the embedding material is formed; and
detaching the composite body from the carrier.

21. The method according to claim 20, wherein the reflector is formed as a flat sheet or as a flat film, a metallic leadframe or a metal film.

22. The method according to claim 20, wherein the optoelectronic semiconductor chip projects beyond a top side of the structured reflector.

23. The method according to claim 20, wherein the carrier is provided with an adhesive film releasable by thermal treatment or electromagnetic irradiation arranged at its top side, and
the reflector is arranged on the adhesive film.

24. The method according to claim 20, wherein one or more electrical contact pads of the optoelectronic semiconductor chip are arranged at the underside of the optoelectronic semiconductor chip.

25. The method according to claim 20, wherein the optoelectronic semiconductor chip is formed as a flip-chip.

26. The method according to claim 20, wherein the optoelectronic semiconductor chip is formed as a volume emitting light-emitting diode chip.

27. The method according to claim 20, wherein the top side of the optoelectronic semiconductor chip is covered by the embedding material.

28. The method according to claim 20, wherein the embedding material comprises a silicone.

29. The method according to claim 20, wherein the embedding material comprises embedded wavelength-converting particles.

30. The method according to claim 20, wherein arranging the embedding material is carried out by a molding or casting process.

31. The method according to claim 20, further comprising, before arranging the embedding material:
arranging a film comprising a wavelength-converting material above the top side of the optoelectronic semiconductor chip, wherein the film is embedded into the embedding material such that the composite body also comprises the film.

32. The method according to claim 20, wherein the optoelectronic semiconductor chip is arranged in the opening of the reflector such that a distance between the optoelectronic semiconductor chip and the reflector is of identical magnitude on all sides of the optoelectronic semiconductor chip.

33. The method according to claim 20, wherein the reflector is formed as a grid comprising a plurality of openings.

34. The method according to claim 33,
wherein a plurality of optoelectronic semiconductor chips are arranged respectively in openings of the reflector,
the composite body formed comprises all the optoelectronic semiconductor chips,
after detaching the composite body, the method further comprises:
dividing the composite body.

35. An optoelectronic component comprising:
a composite body comprising an embedding material,
a reflector, and
an optoelectronic semiconductor chip,
wherein the optoelectronic semiconductor chip is at least partly embedded into the embedding material,
the optoelectronic semiconductor chip is arranged in an opening of the reflector, and
an underside of the optoelectronic semiconductor chip and an underside of the reflector terminate flush and are at least partly exposed at an underside of the composite body.

36. The optoelectronic component according to claim 35, wherein one or more electrical contact pads of the optoelectronic semiconductor chip are arranged at the underside of the optoelectronic semiconductor chip and exposed at the underside of the composite body.

37. The optoelectronic component according to claim 35, wherein a top side of the optoelectronic semiconductor chip opposite the underside is covered by the embedding material.

38. The optoelectronic component according to claim 35, wherein the optoelectronic component comprises no further major component parts apart from the composite body.

39. The optoelectronic component according to claim 35, wherein a distance between the optoelectronic semiconductor chip and the reflector is of identical magnitude on all sides of the optoelectronic semiconductor chip.
